(19) United States
(12) Patent Application Publication
(10) Pub. No.: US 2012/0141935 A1
(43) Pub. Date: Jun. 7, 2012

(54) DEVELOPER AND ITS USE TO PREPARE LITHOGRAPHIC PRINTING PLATES

(76) Inventors: Bernd Strehmel, Krefeld (DE); Oliver Piestert, Schwetzingen (DE); Harald Baumann, Osterode/ Harz (DE)

(21) Appl. No.: 12/959,440

(22) Filed: Dec. 3, 2010

(51) Int. Cl. G03F 7/20; G03F 7/004; G03F 7/00

(52) U.S. Cl. 430/270.1; 430/331; 430/302

(57) ABSTRACT

A developer solution can be used to prepare lithographic printing plates from negative-working precursors. The developer solution has a pH of at least 4 and up to and including 11. It also comprises both an ethylene/propylene glycol block copolymer and either or both of a sugar alcohol or a mono- or oligosaccharide. This combination of components provides desired processing to provide lithographic printing plates that can be used for printing without any post-development treatments with other solutions.

### FIELD OF THE INVENTION

This invention relates to an aqueous developer and to a method for its use to prepare lithographic printing plates from negative-working lithographic printing plate precursors.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink the ink receptive regions accept the ink and repel the water. The ink is then transferred to the surface of suitable materials upon which the image is to be reproduced. In some instances, the ink can be first transferred to an intermediate blanket that in turn is used to transfer the ink to the surface of the materials upon which the image is to be reproduced.

Lithographic printing plate precursors useful to prepare lithographic (or offset) printing plates typically comprise one or more imageable layers applied over a hydrophilic surface of a substrate (or intermediate layers). The imageable layer(s) can comprise one or more radiation-sensitive components dispersed within a suitable binder. Following imaging, either the exposed regions or the non-exposed regions of the imageable layer(s) are removed by a suitable developer, revealing the underlying hydrophilic surface of the substrate. If the exposed regions are removed, the element is considered as positive-working. Conversely, if the non-exposed regions are removed, the element is considered as negative-working. In each instance, the regions of the imageable layer(s) that remain are ink-receptive, and the regions of the hydrophilic surface revealed by the developing process accept water or aqueous solutions (typically a fountain solution), and repel ink.

“Laser direct imaging” methods (LDI) have been known that directly form an offset printing plate or printing circuit board using digital data from a computer, and provide numerous advantages over the previous processes using masking photographic films. There has been considerable development in this field from more efficient lasers, improved imageable compositions and components thereof.

Various radiation-sensitive compositions are known for use in negative-working lithographic printing plate precursors as described for example in U.S. Pat. No. 6,309,792 (Hauck et al.), U.S. Pat. No. 6,893,797 (Munnelly et al.), U.S. Pat. No. 6,727,281 (Tao et al.), U.S. Pat. No. 6,899,994 (Huang et al.), and U.S. Pat. No. 7,429,445 (Munnelly et al.), U.S. Patent Application Publications 2002/0168494 (Nagata et al.), 2003/0118939 (West et al.), and EP Publications 1,079,276A2 (Lifka et al.) and 1,449,650A2 (Goto et al.).

After imaging, the negative-working lithographic printing plate precursors are developed (processed) to remove the non-imaged (non-exposed) regions of the imageable layer. Simplified processing solutions have been developed to be the only solution that is used to contact the precursor before printing. For example, U.S. Patent Application Publication 2009/0263746 (Ray et al.) describes the use of a single processing solution having a pH of 2 to 11 and containing an anionic surfactant to develop the imaged precursor as well as provide a protective coating over the printing surface. The processing solution can be applied in various ways known in the art including spraying, jetting, dipping, immersing, coating, and wiping techniques. Excess processing solution can be collected in a tank and used repeatedly, and replenished with “fresh” processing solution having the same or more concentrated form, which can be diluted with water.

In the lithographic printing industry, there has been a focus on simple processing of imaged lithographic printing plates. By “simple processing”, we mean that processing (development) occurs in one bath in which the image printing plate precursor is developed and gummed simultaneously without needing of any pre-wash, post-rinse, or additional gumming step. While simple processing sounds easy, it is not. It is a big challenge to design such a system based on a computer to plate application for negative-working imaging chemistry based on using photopolymers that can be processed in one batch. On the other hand, one-bath development has been known for many years for analog printing plates (printing plates imaged using graphic arts films) but they are generally too slow for used with digital printing plate applications.

The most challenging aspects for simple processing are:

developing and gumming must occur in one step without needing of any pre-wash, post-rinse or additional gumming steps,

easy restart on-press even with high loading of the developer,

good ink receptivity of the imaged areas even with high loading of the developer,

a clean plate evaluation in the non-imaged areas after storage for several days even with high loading of the developer demonstrating efficient gumming, that is, no post-development in the printing plate after storage for several days (indicative of high chemical resistance against processing chemicals), and

processing at a lower pH without taking up carbon dioxide.

Thus, there is a need in the industry for a way to process negative-working lithographic printing plates in a single developer bath without the need for further processing steps before printing.

### SUMMARY OF THE INVENTION

This invention provides an aqueous developer composition for processing imaged negative-working lithographic printing plate precursors, the developer having a pH of at least 4 and up to and including 13, and comprising both the following (a) and (b):

(a) at least one ethylene glycol/propylene glycol block copolymer in an amount of at least 1 weight %, and

(b) one or more compounds selected from the group consisting of the following (i), (ii), and (iii) in a total amount of at least 1 weight %:
(i) at least one non-reducing sugar alcohol having the formula H(HCHO)ₙ₊₁H wherein n is 5 or 6,
(ii) at least one non-reducing monosaccharide having the formula H(HCHO)ₙHCO wherein n is 5 or 6, and
(iii) at least one non-reducing oligosaccharide having the formula H(HCHO)ₙHCO wherein n is 5 or 6.

This aqueous developer composition can be used in the method of this invention of providing a lithographic printing plate that comprises:

A) imagewise exposing a negative-working lithographic printing plate precursor having a hydrophilic substrate and an imageable layer disposed on the hydrophilic substrate, to provide exposed and non-exposed regions in the imageable layer of the imagewise exposed precursor,

the imageable layer comprising a free radically polymerizable component, an initiator composition that provides free radicals upon imagewise exposure, a radiation absorbing compound, and a polymer binder, and

B) with or without a preheat step, processing the imagewise exposed precursor with the aqueous developer composition of this invention, to remove the non-exposed regions in the imageable layer.

This invention also provides a kit comprising:

one or more negative-working lithographic printing plate precursors having a hydrophilic substrate and an imageable layer disposed on the hydrophilic substrate, the imageable layer comprising a free radically polymerizable component, an initiator composition that provides free radicals upon imagewise exposure, a radiation absorbing compound, and a polymer binder, and

the aqueous developer composition of this invention.

In some embodiments, this kit contains an aqueous developer composition that has a pH of at least 4 and up to and including 11 and is free of silicates and metasilicates.

The present invention provides an aqueous developer that is used in a simple processing method in which further contact with additional processing solutions, such as rinsing and gumming solutions, is not needed. Thus, the single development step is used as the entire processing treatment for both IR and UV imaged precursors. These advantages were achieved using the aqueous developer of this invention that comprises at least two specific components: (a) an ethylene glycol/propylene glycol block copolymer in an amount of at least 1 weight %, and (b) either a sugar alcohol having a chain length of 5 or 6 carbon atoms, or a mono- or oligosaccharide in an amount of at least 1 weight %. Developers having either component (a) or (b) alone do not achieve the same results as the combination of components.

### DETAILED DESCRIPTION OF THE INVENTION

### Definitions

Unless the context indicates otherwise, when used herein, the terms “negative-working lithographic printing plate precursor”, “lithographic printing plate precursor”, “printing plate precursor”, and “precursor” are meant to be references to elements that can be processed using the present invention.

Also, unless the context indicates otherwise, when used herein, the terms “aqueous developer”, “developer”, “processing solution”, “aqueous developer composition”, and similar terms are meant to refer to embodiments of the present invention.

In addition, unless the context indicates otherwise, the various components described herein such as “infrared absorbing compound”, “infrared radiation absorbing compound”, “initiator”, “co-initiator”, “free radically polymerizable component”, “polymeric binder”, and various developer components described below, also refer to mixtures of such components. Thus, the use of the articles “a”, “an”, and “the” is not necessarily meant to refer to only a single component.

Moreover, unless otherwise indicated, percentages refer to percents by total dry weight, for example, weight % based on total solids of either an imageable layer or radiation-sensitive composition. Unless otherwise indicated, the percentages can be the same for either the dry imageable layer or the total solids of radiation-sensitive composition. When referring to developers as described below, weight % is generally based on the total developer weight including the water and any other solvents that are present.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996) or those described by Jonas and Theato in “Glosser zu Begriffen mit Bezug zu Kinetik, Thermodynamik and Mechanismen von Polymerization”, Angewandte Chemie 121, 9725-9738, 2009, doi: 10.1002/ange.200805608. However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imaging of Lithographic Printing Plate Precursors

During use, a negative-working lithographic printing plate precursor is exposed to a suitable source of exposing radiation depending upon the radiation absorbing compound present in the radiation-sensitive composition, at a wavelength of from about 250 to about 450 nm or from about 700 to about 1500 nm. For example, imaging can be carried out using imaging or exposing radiation, such as from a near infrared or an infrared laser (or an array of lasers) at a wavelength of at least 700 nm and up to and including about 1400 nm and typically at least 700 nm and up to and including 1200 nm. Imaging can be carried out using imaging radiation at multiple wavelengths at the same time if desired. Thus, this imaging provides both exposed (and hardened) regions and non-exposed (developer soluble or developer dispersible) regions in the imageable layer disposed on the hydrophilic substrate.

The laser used to expose the lithographic printing plate precursor is usually a diode laser (or array of diode lasers), because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit near infrared and infrared radiation at a wavelength of at least 800 nm and up to and including 1120 nm.

The imaging apparatus can function solely as a platesetter or it can be incorporated directly into a lithographic printing press. In the latter case, printing may commence immediately after imaging and development without further contact with any processing solutions (such as rinse or gumming solutions), thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Kodak Trendsetter platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared or near-infrared radiation can be carried out generally at imaging energies of at least 30 mJ/cm² and up to and including 500 mJ/cm², and typically at least 50 and up to and including 300 mJ/cm² depending upon the sensitivity of the imageable layer.

Useful UV and “violet” imaging apparatus include Prosetter (from Heidelberger Druckmaschinen, Germany), Luxel V-8 (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), Laserjet (from Krause, Germany), and Andromeda® A750M (from Lithotech, Germany), imagesetters.

Imaging radiation in the UV to visible region of the spectrum, and particularly the UV region (for example at least 350 nm and up to and including 450 nm), can be carried out generally using energies of at least 0.01 mJ/cm² and up to and including 0.5 mJ/cm², and typically at least 0.02 and up to and including about 0.1 mJ/cm². It would be desirable, for example, to image the UV/visible radiation-sensitive lithographic printing plate precursors at a power density in the range of at least 0.5 and up to and including 50 kW/cm² and typically of at least 5 and up to and including 30 kW/cm², depending upon the source of energy (violet laser or excimer sources).

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

After imaging, a heating step (pre-heating) might be used to accelerate the formation of a latent image. This heating step can be realized in so called “preheat units” that can be a separate machine or integrated into the processor that develops the imaged precursor. There are different types of preheat units. The most common ones use infrared radiation or hot air circulation, or combination thereof, to heat the imaged precursor. The temperature used for the purpose is at least 70 and up to and including 200° C. However, it can be advantageous to omit the preheating step to simplify the process for making lithographic printing plates.

A pre-rinse step (before development) can be carried out in a stand-alone apparatus or by manually rinsing the imaged precursor with water or the pre-rinse step can be carried out in a washing unit that is integrated in a processor used for developing the imaged precursor.

### Development and Printing

After thermal imaging, the imaged precursors are processed (developed) “off-press” using the aqueous developer of this invention that has a pH of at least 4 and up to and including 13, or typically at least 4 and up to and including 11. Some embodiments of this invention have a pH of at least 7 and up to and including 10.5 or at least 8 and up to and including 10.5. Processing is carried out for a time sufficient to remove predominantly only the non-exposed regions of the imaged imageable layer of negative-working lithographic printing plate precursors to reveal the hydrophilic surface of the substrate, but not long enough to remove significant amounts of the exposed regions. The revealed hydrophilic surface repels inks while the exposed regions containing polymerized or crosslinked polymer accept ink. Thus, the non-exposed regions to be removed are “soluble” or “removable” in the aqueous developer because they are removed, dissolved, or dispersed within it more readily than the regions that are to remain. The term “soluble” also means “dispersible”.

Development can be accomplished using what is known as “manual” development, “dip” development, or processing with an automatic development apparatus (processor). In the case of “manual” development, development is conducted by rubbing the entire imaged precursor with a sponge or cotton pad sufficiently impregnated with aqueous developer (described below), and optionally followed by rinsing with water. “Dip” development involves dipping the imaged precursor in a tank or tray containing the appropriate aqueous developer for at least 10 and up to and including 60 seconds under agitation with or without rubbing with a sponge or cotton pad. The use of an automatic development apparatus is well known and generally includes pumping an aqueous developer into a developing tank or ejecting it from spray nozzles. The apparatus can also include a suitable rubbing mechanism (for example a brush or roller) and a suitable number of conveyance rollers. Some developing apparatus include laser exposure means and is divided into imaging section and developing sections.

During development, the seasoned aqueous developer can be replenished continuous or intermittently with fresh aqueous developer, or it can be similarly replenished merely with water or with a replenisher having stronger activity or amounts of the various components. In still other embodiments, development can be carried out without any replenishment of the aqueous developer.

One useful method and apparatus for processing imaged negative-working lithographic printing plate precursors is described in copending and commonly assigned U.S. Ser. No. 1______ (filed by Jarek, Balbinot, and Baumann on even date herewith, and entitled DEVELOPING LITHOGRAPHIC PRINTING PLATE PRECURSORS IN SIMPLE MANNER, Attorney Docket 96523/JLT). In this processing method, only water is added to the aqueous developer in a manner to keep the concentration of non-volatile solids relatively constant, but the overall volume of the developer is gradually reduced. However, the processing cycle is increased overall from what it would be if no water is added to the aqueous developer.

The aqueous developers of this invention comprise one or more ethylene glycol/propylene glycol block copolymers having one or more blocks of polypropylene glycol and one or more blocks of polyethylene glycol. For example, the block copolymers can have any of the structures: PPG-PEG, PPG-PEG-PPG, PEG-PPG-PEG, PEG-PPG-PEG-PPG, and others that would be readily apparent to a skilled worker. These block copolymers are present in an amount of at least 1 weight % and up to and including 50 weight %, or typically at least 1 and up to and including 20 weight %, or more likely at least 1 and up to and including 5 weight %, based on total aqueous developer weight. Such block copolymers generally have a weight average molecular weight of at least 400 and up to and including 15,000. These block copolymers can be prepared using known starting materials and procedures, and many useful materials are commercially available, including for example, various block copolymers available under the Pluronic® trademark from BASF. Several examples are demonstrated in the Invention Examples below. Some of these block copolymers are in solid form at room temperature while others are viscous liquids at room temperature.

These aqueous developers also include one or a combination of compounds selected from the group consisting of (i), (ii), and (iii) compounds:

(i) at least one non-reducing sugar alcohol having the general formula H(HCHO)ₙ₊₁H wherein n is 5 or 6,

(ii) at least one non-reducing monosaccharide having the general formula H(HCHO)ₙHCO wherein n is 5 or 6, and

(iii) at least one non-reducing oligosaccharide having the general formula H(HCHO)ₙHCO wherein n is 5 or 6.

Thus, this component of the aqueous developers can be a single one of the noted (i), (ii), and (iii) compounds, or a combination of two or more of the (i), (ii), and (iii) compounds.

The total of the (i), (ii), and (iii) compounds in the aqueous developers is at least 1 weight % and up to and including 50 weight %, or typically at least 1 and up to and including 20 weight %, or even at least 5 and up to and including 15 weight %, based on total aqueous developer weight.

By “non-reducing”, we mean that the sugar alcohols, and mono- or oligosaccharides have no reducing properties due to the absence of free aldehyde and ketone groups. Representative (ii) and (iii) compounds derived from pentose or hexose include but are not limited to, mannose, lactose, xylose, desoxyribose, ribulose, glucose, fructose, furanose, pyranose, sucrose, galatose, maltose, raffinose, and starches. Combinations of these compounds can also be used.

Useful sugar alcohols can be obtained from natural sources or be prepared by reducing sugars with hydrogenation and include but are not limited to, D,L-arabitol, ribitol, sorbitol, D,L-xylitol, D,L-mannitol, D,L-iditol, D,L-talitol, meso-inositol, dulcitol, and alloducitol.

The developer compositions are particularly useful if they include one or more of mannose, lactose, xylose, desoxyribose, ribulose, glucose, sorbitol, and xylitol.

The (i), (ii), and (iii) compounds can be obtained from a number of commercial sources.

It is also desirable that the weight ratio of the block copolymer to the total (i), (ii), and (iii) compounds is from 20:1 to and including 1:20, or typically from 1:1 to and including 1:5.

The aqueous developers can also include one or more nonionic, anionic, or amphoteric surfactants, chelating agents (such as salts of ethylenediaminetetraacetic acid), alcoholamines (such as mono- and dialkanol amines, for example ethanolamine, diethanolamine, triethanolamine, and Quadrol® L), organic solvents (such as benzyl alcohol), wetting agents, anti-foaming agents, biocides, complexing agents, organic solvents, anticorrosive agents, antiseptic agents, inorganic salts, and organic amine ink receptivity agents. Alkaline components such as inorganic silicates, inorganic metasilicates, organic metasilicates, hydroxides (such as sodium, potassium, and quaternary ammonium hydroxides), phosphates, and bicarbonates are generally absent from the aqueous developers. In particular, the aqueous developers are free of silicates and metasilicates. Any amines can be present in an amount of up to 30 weight % or more typically at least 1 and up to and including 10 weight %, based on total aqueous developer weight.

One or more anionic, nonionic, cationic, or amphoteric surfactants can be present in an amount of at least 0.5 and up to 40 weight %, based on total aqueous developer weight. Mixtures of the same or different class of surfactants can be present such that the total amount of all surfactants is no more than 40 weight %.

Useful anionic surfactants include but are not limited to, surfactants with carboxylic acid, sulfonic acid, or phosphonic acid groups (or salts thereof). Anionic surfactants having sulfonic acid (or salts thereof) groups are particularly useful. For example, anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypoly-oxyethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphate alkylester, salts of alkylsulfuric esters, sulfuric esters of polyoxy-ethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhdyride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful. Particular examples of such surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

Useful nonionic surfactants include but are not limited to, nonionic surfactants as described in [0029] or hydrophilic polymers described in [0024] of EP 1,751,625 (Van Damme et al.), incorporated herein by reference. Suitable examples of the nonionic surfactants include polyoxyethylene alkyl ethers, polyoxyethylene phenyl ethers, polyoxyethylene 2-naphthyl ethers, polyoxyethylene alkyl phenyl ethers, polyoxyethylene polystyryl phenyl ethers, polyoxyethylene polyoxypropylene alkyl ethers, polyoxyethylene polyoxypropylene block polymers, partial esters of glycerinaliphatic acids, partial esters of sorbitanaliphatic acid, partial esters of pentaerytluitolaliphatic acid, propyleneglycolmonoaliphatic esters, partial esters of sucrosealiphatic acids, partial esters of polyoxyethylenesorbitanaliphatic acid, partial esters of polyoxyethylenesorbitolaliphatic acids, polyethyleneglycolaliphatic esters, partial esters of poly-glycerinaliphatic acids, polyoxyethylenated castor oils, partial esters of polyoxyethyleneglycerin-aliphatic acids, aliphatic diethanolamides, N,N-bis-2-hydroxyalkylamines, polyoxyethylene alkylamines, triethanolaminealiphatic esters, and trialkylamine oxides. Particularly useful nonionic surfactants are polyoxyethylene phenyl ethers and polyoxyethylene-2-naphthyl ethers. Other useful nonionic surfactants include Mazol® PG031-K (a triglycerol monooleate, Tween® 80 (a sorbitan derivative), Pluronic® L62LF (a block copolymer of propylene oxide and ethylene oxide), and Zonyl® FSN (a fluorocarbon), and a nonionic polyglycol.

Useful amphoteric surfactants include but are not limited to, N-alkylamino acid triethanol ammonium salts, cocamidopropyl betaines, cocamidoalkyl glycinates, sodium salt of a short chain alkylaminocarboxylate, N-2-hydroxyethyl-N-2-carboxyethyl fatty acid amidoethylamin sodium salts, and carboxcylic acid amidoetherpropionates.

Useful cationic surfactants include but are not limited to, tetraalkyl ammoniumchlorides such as tetrabutyl ammoniumchloride and tetramethyl ammoniumchloride, and polypropoxylated quaternary ammonium chlorides.

Following processing, the resulting lithographic printing plate can be used for printing without further treatment with any additional solutions such as rinsing or gumming solutions.

The resulting lithographic printing plate can also be baked in a postbake operation can be carried out, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and developed precursor. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material.

### Substrates

The substrate used to prepare the lithographic printing plate precursors comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful substrate is an aluminum-containing support that can be treated using techniques known in the art, including roughening of some type by physical (mechanical) graining, electrochemical graining, or chemical graining, usually followed by acid anodizing. The aluminum-containing support can be roughened by physical or electrochemical graining and then anodized using phosphoric or sulfuric acid (or a mixture of both phosphoric and sulfuric acids) and conventional procedures. A useful hydrophilic lithographic substrate is an electrochemically grained and sulfuric acid-anodized aluminum-containing substrate that provides a hydrophilic surface for lithographic printing.

Sulfuric acid anodization of the aluminum support generally provides an oxide weight (coverage) on the surface of at least 1.5 and up to and including 5 g/m², and can provide longer press life. Phosphoric acid anodization generally provides an oxide weight on the surface of at least 1 and up to and including 5 g/m².

The aluminum-containing substrate can also be post-treated with, for example, a silicate, dextrin, calcium zirconium fluoride, hexafluorosilicic acid, poly(vinyl phosphoric acid) (PVPA), vinyl phosphonic acid copolymer, poly[(meth)acrylic acid], or an acrylic acid copolymer to increase hydrophilicity. Still further, the aluminum-containing substrate can be treated with a phosphate solution that can further contain an inorganic fluoride (PF). It is particularly useful to post-treat the sulfuric acid-anodized aluminum-containing substrate with either poly(acrylic acid) or poly(vinyl phosphonic acid).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Negative-Working Lithographic Printing Plate Precursors

The precursors can be formed by suitable application of a radiation-sensitive composition as described below to a suitable substrate (described above) to form an imageable layer. There is generally only a single imageable layer comprising the radiation-sensitive composition and can be the outermost layer in the element. However, a topcoat can be present over the imageable layers.

Negative-working lithographic printing plate precursors are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. No. 4,511,645 (Koike et al.), U.S. Pat. No. 6,027,857 (Teng), U.S. Pat. No. 6,309,792 (Hauck et al.), U.S. Pat. No. 6,569,603 (Furukawa et al.), U.S. Pat. No. 6,899,994 (Huang et al.), U.S. Pat. No. 7,045,271 (Tao et al.), U.S. Pat. No. 7,049,046 (Tao et al.), U.S. Pat. No. 7,261,998 (Hayashi et al.), U.S. Pat. No. 7,279,255 (Tao et al.), U.S. Pat. No. 7,285,372 (Baumann et al.), U.S. Pat. No. 7,291,438 (Sakurai et al.), U.S. Pat. No. 7,326,521 (Tao et al.), U.S. Pat. No. 7,332,253 (Tao et al.), U.S. Pat. No. 7,442,486 (Baumann et al.), U.S. Pat. No. 7,452,638 (Yu et al.), U.S. Pat. No. 7,524,614 (Tao et M.), 7,560,221 (Timpe et al.), U.S. Pat. No. 7,574,959 (Baumann et al.), U.S. Pat. No. 7,615,323 (Strehmel et al.), and U.S. Pat. No. 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.), all of which are incorporated herein by reference. Other negative-working compositions and elements are described for example in U.S. Pat. No. 6,232,038 (Takasaki), U.S. Pat. No. 6,627,380 (Saito et al.), U.S,. Pat. No. 6,514,657 (Sakurai et al.), U.S. Pat. No. 6,808,857 (Miyamoto et al.), and U.S. Patent Publication 2009/0092923 (Hayashi), all of which are incorporated herein by reference.

The radiation-sensitive compositions and imageable layers used in such precursors can generally include one or more polymeric binders that facilitate the developability of the imaged precursors.

Useful polymeric binders can be homogenous, that is, non-particulate or dissolved in the coating solvent, or they can exist as discrete particles, or a mixture of homogeneous and particulate polymeric binders can be used.

For example, useful polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.), all of which are incorporated herein by reference. Also useful are the vinyl carbazole polymers described in U.S. Pat. No. 7,175,949 (Tao et al.), and the polymers having pendant vinyl groups as described in U.S. Pat. No. 7,279,255 (Tao et al.), both patents being incorporated herein by reference. Useful are random copolymers derived from polyethylene glycol methacrylate/acrylonitrile/styrene monomers in random fashion and in particulate form, dissolved random copolymers derived from carboxyphenyl methacrylamide/acrylonitrile/-methacrylamide/N-phenyl maleimide, random copolymers derived from polyethylene glycol methacrylate/acrylonitrile/vinyl carbazole/styrene/-methacrylic acid, random copolymers derived from N-phenyl maleimide/methacrylamide/methacrylic acid, random copolymers derived from urethane-acrylic intermediate A (the reaction product ofp-toluene sulfonyl isocyanate and hydroxyl ethyl methacrylate)/acrylonitrile/N-phenyl maleimide, and random copolymers derived from N-methoxymethyl methacrylamide/methacrylic acid/acrylonitrile/n-phenylmaleimide. By “random” copolymers, we mean the conventional use of the term, that is, the structural units in the polymer backbone that are derived from the monomers are arranged in random order as opposed to being block copolymers, although two or more of the same structural units can be in a chain incidentally.

The polymeric binders can also be selected from any alkaline solution soluble (or dispersible) polymer having an acid value of at least 20 and up to and including 400 (typically at least 30 and up to and including 200). The following described polymeric binders are particularly useful in the manner but this is not an exhaustive list:

I. Polymers formed by polymerization of a combination or mixture of (a) (meth)acrylonitrile, (b) poly(alkylene oxide) esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference. Some particularly useful polymeric binders in this class are derived from one or more (meth)acrylic acids, (meth)acrylate esters, styrene and its derivatives, vinyl carbazoles, and poly(alkylene oxide) (meth)acrylates.

II. Polymers having pendant allyl ester groups as described in U.S. Pat. No. 7,332,253 (Tao et al.) that is incorporated herein by reference. Such polymers can also include pendant cyano groups or have recurring units derived from a variety of other monomers as described in Col. 8, line 31 to Col. 10, line 3 of the noted patent.

III. Polymers having all carbon backbones wherein at least 40 and up to and including 100 mol % (and typically at least 40 and up to and including 50 mol %) of the carbon atoms forming the all carbon backbones are tertiary carbon atoms, and the remaining carbon atoms in the all carbon backbone being non-tertiary carbon atoms. By “tertiary carbon”, we refer to a carbon atom in the all carbon backbone that has three valences filled with radicals or atoms other than a hydrogen atom (which fills the fourth valence). By “non-tertiary carbon”, we mean a carbon atom in the all carbon backbone that is a secondary carbon (having two valences filled with hydrogen atoms) or a quaternary carbon (having no hydrogen atoms attached). Typically, most of the non-tertiary carbon atoms are secondary carbon atoms. One way to represent a tertiary carbon atom in the all carbon backbone is with the following Structure (T-CARBON):

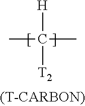

wherein T₂ is a group other than hydrogen provided that T₂ does not include an ethylenically unsaturated free radically reactive group (such as a —C═C— group). In many embodiments, T₂ is a pendant group selected from N-carbazole, aryl (defined similarly as for Ar below), halo, cyano, —C(═O)R, —C(═O)Ar, —C(═O)OR, —C(═O)OAr, —C(═O)NHR, and —C(═O)NHAr pendant groups, wherein R is hydrogen or an alkyl, cycloalkyl, halo, alkoxy, acyl, or acyloxy group, and Ar is an aryl group other than a styryl group. The quaternary carbon atoms present in the all carbon backbone of the polymeric binder can also have the same or different pendant groups filling two of the valences. For example, one or both valences can be filled with the same or different alkyl groups as defined above for R, or one valence can be filled with an alkyl group and another valence can be filled with a N-carbazole, aryl other than a styryl group, halo, cyano, —C(═O)R, —C(═O)Ar, —C(═O)OR, —C(═O)OAr, —C(═O)NHR, or —C(═O)NHAr pendant group, wherein R and Ar are as defined above. The pendant groups attached to the tertiary and quaternary carbons in the all carbon backbone can be the same or different and typically, they are different. It should also be understood that the pendant groups attached to the various tertiary carbon atoms can be the same throughout the polymeric molecule, or they can be different. For example, the tertiary carbon atoms can be derived from the same or different ethylenically unsaturated polymerizable monomers. Moreover, the quaternary carbon atoms throughout the polymeric molecule can have the same or different pendant groups.

In some embodiments, the polymeric binder can be represented by the following Structure:

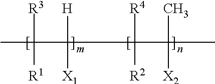

that is defined in more details in U.S. Patent Application Publication 2008-0280229 (Tao et al.) that is incorporated herein by reference.

Representative recurring units comprising tertiary carbon atoms can be derived from one or more ethylenically unsaturated polymerizable monomers selected from vinyl carbazole, styrene and derivatives thereof (other than divinylbenzene and similar monomers that provide pendant carbon-carbon polymerizable groups), acrylic acid, acrylonitrile, acrylamides, acrylates, and methyl vinyl ketone. As noted above, two or more different recurring units can be used. Similarly, representative recurring units with secondary or quaternary carbon atoms can be derived from one or more ethylenically unsaturated polymerizable monomers selected from methacrylic acid, methacrylates, methacrylamides, and α-methylstyrene.

IV. Polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups can be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. No. 4,874,686 (Urabe et al.), U.S. Pat. No. 7,729,255 (Tao et al.), U.S. Pat. No. 6,916,595 (Fujimaki et al.), and U.S. Pat. No. 7,041,416 (Wakata et al.) that are incorporated by reference, especially with respect to the general formulae (1) through (3) noted in EP 1,182,033A1.

V. Polymeric binders can have pendant 1H-tetrazole groups as described in U.S. Patent Application Publication 2009-0142695 (Baumann et al.) that is incorporated herein by reference.

VI. Still other useful polymeric binders can be homogenous, that is, dissolved in the coating solvent, or can exist as discrete particles and include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (noted above) and U.S. Pat. No. 6,309,792 (Hauck et al.), U.S. Pat. No. 6,352,812 (Shimazu et al.), U.S. Pat. No. 6,569,603 (noted above), and U.S. Pat. No. 6,893,797 (Munnelly et al.). Also useful are the vinyl carbazole polymers described in U.S. Pat. No. 7,175,949 (Tao et al.).

Other useful polymeric binders are particulate poly(urethane-acrylic) hybrids that are distributed (usually uniformly) throughout the imageable layer. Each of these hybrids has a molecular weight of at least 50,000 and up to and including 500,000. Such particulate polymeric binders include but are not limited to, those that are not generally crosslinkable and are can be present at least partially as discrete particles (not-agglomerated). The particulate polymeric binders exist at room temperature as discrete particles, for example in an aqueous dispersion. Such polymeric binders generally have a molecular weight (Mₙ) of at least 5,000 and typically at least 20,000 and up to and including 100,000, or at least 30,000 and up to and including 80,000, as determined by Gel Permeation Chromatography.

Useful particulate polymeric binders generally include polymeric emulsions or dispersions of polymers having hydrophobic backbones to which are directly or indirectly linked pendant poly(alkylene oxide) side chains (for example at least 10 alkylene glycol units), cyano side chains, or both types of side chains, that are described for example in U.S. Pat. No. 6,582,882 (Pappas et al.), U.S. Pat. No. 6,899,994 (Huang et al.), U.S. Pat. No. 7,005,234 (Hoshi et al.), and U.S. Pat. No. 7,368,215 (Munnelly et al.) and US Patent Application Publication 2005/0003285 (Hayashi et al.), all of which are incorporated herein by reference. More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, in recurring units arranged in random fashion to form the polymer backbone, and various hydrophilic polymeric binders that can have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the particulate polymeric binders can also have a backbone comprising multiple (at least two) urethane moieties. Such polymeric binders generally have a molecular weight (Mₙ) of at least 2,000 and typically at least 100,000 and up to and including 500,000, or at least 100,000 and up to and including 300,000, as determined by dynamic light scattering.

Additional useful polymeric binders are particulate poly(urethane-acrylic) hybrids that are distributed (usually uniformly) throughout the imageable layer. Each of these hybrids has a molecular weight of at least 50,000 and up to and including 500,000. These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that can also include commercial surfactants, anti-foaming agents, dispersing agents, anti-corrosive agents, and optionally pigments and water-miscible organic solvents.

These polymeric binders are generally present in an amount of at least 5 and up to and including 70 weight % of the radiation-sensitive composition (and therefore, imageable layer).

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane(meth)acrylates or urethane(meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.). Other useful free radically polymerizable components include those described in U.S. Patent Application Publication 2009/0142695 (Baumann et al.), which radically polymerizable components include 1H-tetrazole groups.

Still other useful free radically polymerizable components are the polymerizable oligomers described in U.S. Patent Application Publications 2008/0248424 (Baumann et al.) and 2009/0011363 (Baumann et al.), both of which are incorporated herein by reference.

In addition to, or in place of the free radically polymerizable components described above, the radiation-sensitive composition can include polymeric materials that include side chains attached to the backbone, which side chains include one or more free radically polymerizable groups (such as ethylenically unsaturated groups) that can be polymerized (crosslinked) in response to free radicals produced by the initiator composition (described below). There can be at least two of these side chains per molecule. The free radically polymerizable groups (or ethylenically unsaturated groups) can be part of aliphatic or aromatic acrylate side chains attached to the polymeric backbone. Generally, there are at least 2 and up to and including 20 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

This radiation-sensitive composition also includes an initiator composition that includes one or more initiators that are capable of generating free radicals sufficient to initiate polymerization of all the various free radically polymerizable components upon exposure of the composition to imaging infrared radiation. The initiator composition is generally responsive, for example, to electromagnetic radiation in the near infrared and infrared spectral regions, corresponding to the broad spectral range of at least 700 nm and up to and including 1400 nm, and typically radiation of at least 700 nm and up to and including 1250 nm. Alternatively, the initiator composition may be responsive to exposing radiation in the violet region of at least 250 and up to and including 450 nm and typically at least 300 and up to and including 450 nm.

More typically, the initiator composition includes one or more an electron acceptors and one or more co-initiators that are capable of donating electrons, hydrogen atoms, or a hydrocarbon radical.

In general, suitable initiator compositions for radiation-sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts).

Hexaarylbiimidazoles, onium compounds, and thiol compounds as well as mixtures of two or more thereof are desired coinitiators or free radical generators, and especially hexaarylbiimidazoles and mixtures thereof with thiol compounds are useful. Suitable hexaoryibiimidazoks are also described in U.S. Pat. No. 4,565,769 (Dueber et al.) and U.S. Pat. No. 3,445,232 (Shirey) and can be prepared according to known methods, such as the oxidative dimerization of triarylimidazoles.

Useful initiator compositions for IR radiation-sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions can be supplied as part of substituted or unsubstituted diaryliodonium salts that are combinations of Structures (I) and (II) described in Cols. 6-8 of U.S. Pat. No. 7,524,614 (Tao et al.) that is incorporated herein by reference.

Useful near IR and IR radiation-sensitive initiator compositions can comprise one or more diaryliodonium borate compounds. Representative iodonium borate compounds useful in this invention include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexyl-phenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexyl-phenyliodonium tetrakis(penta-fluorophenyl)borate, 4-methylphenyl-4′-dodecylphenyliodonium tetrakis(4-fluorophenyl)borate, bis(dodecylphenyl)-iodonium tetrakis(pentafluorophenyl)-borate, and bis(4-t-butylphenyl)iodonium tetralds(1-imidazolypborate. Useful compounds include bis(4-t-butylphenyl)-iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

The imageable layers comprise a radiation-sensitive imaging composition that includes one or more infrared radiation absorbing compounds or one or more UV sensitizers. The total amount of one or more infrared radiation absorbing compounds or sensitizers is at least 1 and up to and including 30 weight %, or typically at least 5 and up to and including 20 weight %, based on the imageable layer total solids.

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 375 nm and up to and including 475 nm. Useful sensitizers for such compositions include certain pyrilium and thiopyrilium dyes and 3-ketocoumarins. Some other useful sensitizers for such spectral sensitivity are described for example, in U.S. Pat. No. 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated it-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Other useful sensitizers for the violet region of sensitization are the 2,4,5-triaryloxazole derivatives as described in WO 2004/074930 (Baumann et al.). These compounds can be used alone or with a co-initiator as described above. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan or oxazole ring, or the Structure G-(Ar₁)₂ wherein G is an oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Thus, the aryl groups can be substituted with one or more R′₁ through R′₃ groups, respectively, that are independently hydrogen or a substituted or unsubstituted alkyl group having from 1 to 20 carbon atoms (such as methyl, ethyl, iso-propyl, n-hexyl, benzyl, and methoxymethyl groups) substituted or unsubstituted carbocyclic aryl group having 6 to 10 carbon atoms in the ring (such as phenyl, naphthyl, 4-methoxyphenyl, and 3-methylphenyl groups), substituted or unsubstituted cycloalkyl group having 5 to 10 carbon atoms in the ring, a —N(R′₄)(R′₅) group, or a —OR′₆ group wherein R′₄ through R′₆ independently represent substituted or unsubstituted alkyl or aryl groups as defined above. At least one of R′₁ through R′₃ is an —N(R′₄)(R′₅) group wherein R′₄ and R′₅ are the same or different alkyl groups. Useful substituents for each Ar₁ group include the same or different primary, secondary, and tertiary amines.

Still another class of useful violet radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, oxazole, or oxadiazole ring. An is the same as defined above, and Ar₂ can be the same or different aryl group as Ar₁. “Arylene” can be any of the aryl groups defined for Ar₁ but with a hydrogen atom removed to render them divalent in nature.

Some useful near infrared and infrared radiation absorbing compounds are sensitive to both infrared radiation (typically of at least 700 and up to and including 1400 nm) and visible radiation (typically of at least 450 and up to and including 700 nm). These compounds also have a tetraaryl pentadiene chromophore. Such chromophore generally includes a pentadiene linking group having 5 carbon atoms in the chain, to which are attached two substituted or unsubstituted aryl groups at each end of the linking group. These aryl groups can be substituted with the same or different tertiary amine groups. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain. Other details of such compounds are provided in U.S. Pat. No. 7,429,445 (Munnelly et al.).

Other useful include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo)polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), U.S. Pat. No. 6,569,603 (noted above), U.S. Pat. No. 6,787,281 (Tao et al.), U.S. Pat. No. 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (noted above), U.S. Pat. No. 6,264,920 (Achilefu et al.), U.S. Pat. No. 6,153,356 (noted above), and U.S. Pat. No. 5,496,903 (Watanabe et al.). Suitable dyes can be formed using conventional methods and starting materials or obtained from various commercial sources including American Dye Source (Bale D'Urfe, Quebec, Canada) and FEW Chemicals (Germany). Other useful dyes for near infrared diode laser beams are described in U.S Pat. No. 4,973,572 (DeBoer).

Useful IR-radiation sensitive compositions are described, for example, in U.S. Pat. No. 7,452,638 (Yu et al.), and U.S. Patent Application Publications 2008/0254387 (Yu et al.), 2008/0311520 (Yu et al.), 2009/0263746 (Ray et al.), and 2010/0021844 (Yu et al.).

The imageable layer can also include a poly(alkylene glycol) or an ether or ester thereof that has a molecular weight of at least 200 and up to and including 4000. The imageable layer can further include a poly(vinyl alcohol), a poly(vinyl pyrrolidone), poly(vinyl imidazole), or polyester in an amount of up to and including 20 weight % based on the total dry weight of the imageable layer.

Additional additives to the imageable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.). The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. The imageable layer also optionally includes a phosphate (meth)acrylate having a molecular weight generally greater than 250 as described in U.S. Pat. No. 7,429,445 (Munnelly et al.) that is incorporated herein by reference.

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer.

The outermost layer can be a water-soluble or water-dispersible overcoat (also sometimes known as an “oxygen impermeable topcoat” or “oxygen bather layer”) disposed over the imageable layer. Such overcoat layers can comprise one or more water-soluble poly(vinyl alcohol)s having a saponification degree of at least 80% and generally have a dry coating weight of at least 0.1 and up to and including 2 g/m² in which the water-soluble poly(vinyl alcohol)s comprise at least 60% and up to and including 99.5% of the dry overcoat layer weight.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a random copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), and random copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.) that is incorporated by reference.

Illustrative of such manufacturing methods is mixing the various components needed for a specific imaging chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readilylnown in the art, as well as mixtures thereof], applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0.1 and up to and including 3 g/m² or at least 0.5 and up to and including 2.5 g/m².

Layers can also be present under the imageable layer to enhance developability or to act as a thermal insulating layer.

Once the various layers have been applied and dried on the substrate, the negative-working imageable elements can be enclosed in water-impermeable material that substantially inhibits the transfer of moisture to and from the element and “heat conditioned” as described in U.S. Pat. No. 7,175,969 (noted above) that is incorporated herein by reference.

The lithographic printing plate precursors can be stored and transported as stacks of precursors within suitable packaging and containers known in the art.

The present invention provides at least the following embodiments and combinations thereof, but other combinations of features are considered to be within the present invention as a skilled artisan would appreciate from the teaching of this disclosure:

1. An aqueous developer composition for processing imaged negative-working lithographic printing plate precursors, the developer having a pH of at least 4 and up to and including 13, and comprising both the following (a) and (b):

(a) at least one ethylene glycol/propylene glycol block copolymer in an amount of at least 1 weight %, and

(b) one or more compounds selected from the group consisting of the following (i), (ii), and (iii) compounds in a total amount of at least 1 weight %:
(i) at least one non-reducing sugar alcohol having the formula H(HCHO)ₙ₊₁H wherein n is 5 or 6,
(ii) at least one non-reducing monosaccharide having the formula H(HCHO)ₙHCO wherein n is 5 or 6, and
(iii) at least one non-reducing oligosaccharide having the formula H(HCHO)ₙHCO wherein n is 5 or 6.

2. The aqueous developer composition of embodiment 1 wherein the weight ratio of the block copolymer to the total of the (i), (ii), and (iii) compounds is from 1:20 to 20:1.

3. The aqueous developer composition of embodiment 1 or 2 wherein (ii) and (iii) compounds are selected from the group consisting of mannose, lactose, xylose, desoxyribose, ribulose, glucose, fructose, furanose, pyranose, sucrose, galactose, maltose, raffinose, D,L-arabitol, ribitol, sorbitol, and D,L-xylitol, D,L-mannitol, D,L-talitol, meso-inositol, dulcitol, and alloducitol.

4. The aqueous developer composition of any of embodiments 1 to 3 wherein the total amount of (i), (ii), and (iii) compounds is an amount of at least 1 and up to and including 20 weight %.

5. The aqueous developer composition of any of embodiments 1 to 4 wherein the ethylene glycol/propylene glycol block copolymer in an amount of at least 1 and up to and including 20 weight %.

6. The aqueous developer composition of any of embodiments 1 to 5 wherein the ethylene glycol/propylene glycol block copolymer has a weight average molecular weight of at least 400 and up to and including 15,000.

7. The aqueous developer composition of any of embodiments 1 to 6 having a pH of at least 4 and up to and including 11.

8. The aqueous developer composition of any of embodiments 1 to 7 further comprising one or more anionic, nonionic, cationic, or amphoteric surfactants in a total amount of up to 40 weight %.

9. The aqueous developer composition of any of embodiments 1 to 8 further comprising an anionic surfactant in an amount of at least 0.5 and up to and including 5 weight %.

10. The aqueous developer composition of any of embodiments 1 to 9 that is free of silicates and metasilicates.

11. The aqueous developer composition of any of embodiments 1 to 10 further comprising an alcoholamine.

12. A method of providing a lithographic printing plate comprising:

A) imagewise exposing a negative-working lithographic printing plate precursor having a hydrophilic substrate and an imageable layer disposed on the hydrophilic substrate, to provide exposed and non-exposed regions in the imageable layer of the imagewise exposed precursor,

the imageable layer comprising a free radically polymerizable component, an initiator composition that provides free radicals upon imagewise exposure, a radiation absorbing compound, and a polymer binder, and

B) with or without a preheat step, processing the imagewise exposed precursor with the aqueous developer composition of any of embodiments 1 to 11, to remove the non-exposed regions in the imageable layer.

13. The method of embodiment 12 wherein the lithographic printing plate precursor is sensitive to infrared radiation and the imagewise exposing is carried out at the wavelength of at least 700 nm and up to and including 1400 nm.

14. The method of embodiment 12 wherein the lithographic printing plate precursor is sensitive to and imagewise exposed at the wavelength of at least 350 nm and up to and including 450 nm.

15. The method of any of embodiments 12 to 14 wherein the imaged and developed lithographic printing plate is used for printing without any additional solution treatment after the developing step.

16. The method of any of embodiments 12 to 15 wherein processing step B is carried out by intermittent or continuous replenishment using fresh portions of the aqueous developer composition.

17. The method of embodiment 16 wherein the aqueous developer composition is replenished with water only.

18. The method of any of embodiments 12 to 17 wherein processing step B is carried out without any replenishment of the aqueous developer composition.

19. A kit comprising:

one or more negative-working lithographic printing plate precursors having a hydrophilic substrate and an imageable layer disposed on the hydrophilic substrate, the imageable layer comprising a free radically polymerizable component, an initiator composition that provides free radicals upon imagewise exposure, a radiation absorbing compound, and a polymer binder, and

the aqueous developer composition of any of embodiments 1 to 11.

The following Examples are provided to illustrate the practice of this invention and are not meant to be limiting in any manner. The following components and materials were used in the Examples.
Desmodur® N100 Trifunctional isocyanate (biuret of hexamethylene diisocyanate) available from Bayer (Germany)
HEMA (2-Hydroxyethyl)methacrylate
HEPi 2-(2-Hydroxyethyl)-piperidine
HMDI Hexamethylene diisocyanate
Polymer 1 Copolymer derived from methyl allyl methacrylate, methacrylic acid, and isopropylmethacrylamide, 70/10/20 molar ratio, acid number=45 mg KOH/g
Polymer 2 Copolymer derived from 47% styrene, 34% methyl methacrylate, and 19% methacrylic acid (weight)
Polymer 3 Joncryl® 683 acrylic resin from SC Johnson & Son Inc., acid number=162 mg KOH/g
Kayamer PM-2 Ester of 1 mol phosphoric acid and 1.5 mol hydroxyethyl methacrylate, from Nippon Kayaku (Japan)
NK Ester BPE-500 Ethoxylated Bisphenol A having methacrylic end groups, from Shin Nakamura (Japan)
PDISP Pigment dispersion in propylene glycol monomethyl ether containing 9 weight % of copper phthalocyanine and 1 weight % of a poly(vinyl acetal) binder having recurring units derived from 39.9 mol % vinyl alcohol, 1.2 mol % vinyl acetate, 15.4 mol % acetal groups from acetaldehyde, 36.1 mol % acetal groups from butyraldehyde, and 7.4 acetal groups from 4-formylbenzoic acid
Texapon® 842 Sodium octyl sulfate anionic surfactant from Cognis
Quadrol®-L 1,1′,1″,1′″-(Ethanediylnitrilo)tetrakis(2-propanol) from BASF
Amphotensid B5 Cocamidopropyl betaine amphoteric surfactant
Dowanol® DPM Dipropylene glycol methyl ether
Dowanol® TPnB Tripropylene glycol n-butyl ether
Dovvfax™ 8390 Alkyldiphenyloxide disulfonate salt anionic surfactant
Pluriol® E 400 Polyethylene glycol, polyalkylene glycol, polyol from BASF
Dehyton® AB 30 Coco-caprylate betaine amphoteric surfactant, from Cognis
Pluronic® PE10400 PPO/PEO block copolymer, 3250 g/mol, 40% PEO, from BASF
Pluronic® RPE 2035 PPO/PEO block copolymer, 4100 g/mol, 65% PEO, from BASF
Pluronic® PE6800 PPO/PEO block copolymer, 1750 g/mol, 80% PEO, from BASF
Pluronic® PE6400 PPO/PEO block copolymer, 2450 g/mol, 20% PEO, from BASF
Pluronic® PE3100 PPO/PEO block copolymer, 950 g/mol, 10% PEO, from BASF
Pluronic® PE3500 PPO/PEO block copolymer, 950 g/mol, 50% PEO, from BASF
Pluronic® PE4300 PO/EO block copolymer, 1750 g/mol, 30% PEO, from BASF
Pluronic® PE8100 PPO/PEO block copolymer, 2300 g/mol, 10% PEO, from BASF
Polymer 5 Poly(vinyl alcohol) with a saponification degree of 88%
MEK Methyl ethyl ketone

### INVENTION EXAMPLES AND COMPARATIVE EXAMPLES

An electrochemically roughened and anodized aluminum foil with an oxide weight of 3 g/m² was subjected to a post-treatment using an aqueous solution of poly(vinyl phosphoric acid). The average roughness of the surface was 0.55 μm. Imageable layer coating compositions corresponding to TABLES I and II below were applied to the substrate after filtering with a wire bar coater. Each coating was dried for 4 minutes at 90° C. The coatings weights were 1.4 g/m² for the formulations sensitized for 405 nm (TABLE I and II) and 830 nm (TABLE III).

The obtained samples were coated with an aqueous solution of poly(vinyl alcohol) (Celvol® 203 from Air Products, having a hydrolysis degree of 88%) with a wire bar coater to get a printing plate precursor having a dry coating weight after drying for 4 minutes at 90° C. The coating weight of the poly(vinyl alcohol) topcoat was 2.1 g/m².

Lithographic printing plate precursors prepared using the formulations of TABLE I were exposed using an imagesetter (Heidelberg Prosetter), equipped with a laser diode emitting at 405 nm (P=30 mW). An UGRA gray scale V2.4 with defined tonal values was exposed onto the precursors at an exposure energy of 55 μJ/cm². The imaged precursors were heated directly after exposure for 2 minutes to 90° C. and then developed using Invention Developers 1-10 and Comparative Developers 1-4. The results are shown below in TABLE III.

Lithographic printing plate precursors prepared using the formulation described in TABLE II below, that also have the same overcoat as those used for 405 nm exposure, were imaged using a Kodak® Trendsetter 3224 at 830 nm. An UGRA/FOGRA Postscript Strip version 2.0 EPS (available from UGRA), which contains different elements for evaluating the quality of the copies, was used for imaging in both the Invention and Comparative Examples in TABLE III with Kodak® Trendsetter 3244 (at 830 nm). The imaging energy was 70 mJ/cm². The imaged precursors were heated directly after exposure for 2 minutes at 90° C. and the precursors were then developed in one bath using the aqueous developer described below with no prewash, no post-rinse, and no gumming after development in a Raptor Polymer apparatus.

Developing Time:

To measure the developing time for each precursor, unexposed precursor strips of 5×30 cm were dipped into the particular aqueous developer in a glass beaker and every 3 seconds, the strips were lowered 1 cm deeper into the aqueous developer. Prior to this development, the imaged precursors had been treated for 2 minutes in an oven at 90° C. After removing the strips from the developer, the strips were rinsed with water, wiped with an emulsion of water and lithographic printing ink (Offset S 7184, available from Sun Chemical, which contains 10% of calcium carbonate), and finally washed clean. The time to get the first clean step was noted as the developing time.

Length of Run:

To measure the length of run (LOR), lithographic printing plates were loaded in a sheet-fed offset printing machine using abrasive ink (Offset S 7184). The LOR was the number of copies when the first sign of wear in the solid areas of the printing plate became visible. In the same press test, we also used the lithographic printing plates for printing after a long loading cycle. The results regarding developability and behavior on press were compared with lithographic printing plates treated with fresh developers.

Processor Cleanliness:

Processor cleanliness was evaluated after 30 m²/l loading of plates using a Raptor Polymer apparatus (40 liter developer tank volume) using no prewash, no post-rinsing, and no gumming sections. All brushes and rollers were removed in the prewash, post-rinse, and gumming sections. We evaluated the cleanliness as from excellent (Grade 1) when no undesired residue was observed to unacceptable (Grade 6) when sludge and other undesired residue were observed after the loading cycle. The following grades describe the cleanliness of the processor after the loading cycle:

1: excellent,

2: very good with small residue removable by rinsing with water,

3: good with more residues but still removable by rinsing with water,

4: residues not removable by rinsing with water,

5: unacceptable, requiring the use of special cleaning solutions and a cleaning time of about 1 hour,

6: unacceptable with highest sludge, requiring the use of special cleaning solutions and a cleaning time greater than 3 hours.

Running Clean on Press (Number of Printed Sheets):

Each printing plate precursor coated using the imageable layer formulation described in TABLE I or II, which was also coated with overcoat formulation, was imagewise exposed and developer using the aqueous developers described below. Each lithographic printing plate was put on the printing press, printing was begun, and after printing 20,000 impressions, printing was then interrupted for 30 minutes. After this time, printing was restarted and the number of sheets needed to obtain a clean non-image area was noted as a measure for “running clean”.

Ink Receptivity:

Ink receptivity was evaluated at the beginning of each press run, and the number of sheets being necessary to achieve the desired tonal values on the printed sheet, were counted.

De-Wetting Property:

The de-wetting property (drying of the lithographic printing plate) was inspected and the time was estimated when the printing plate looked almost dry after development.

Image Stability after Development:

Printing plate precursors developed in a single bath processor can exhibit “post-development” from processing chemicals that remain on the processed printing plates. These processing chemicals can continue to develop the lithographic printing plate even upon longer storage in the dark. We checked the image stability by keeping a processed plate in the dark at 23° C. and 55% room humidity for 5 days. After this time, each lithographic printing plate was rinsed with water and manually rubbed using a tissue that was filled with a suspension of lithographic printing ink and water. The image on the lithographic printing plate is considered stable when no change of tonal values occurs and the non-image areas do not take up any ink. This means that these areas are clean after inking.

TABLE I

| | |
|---|---|
| 1.44 g | Polymeric binder Polymer 1 |
| 0.08 g | 2-[5-[3,3-Dimethyl-1-(4-sulfobutyl)-1,3-dihydro-indol- |
| | 2-ylidene]-penta-1,3-dienyl]-3,3-dimethyl-1-(4- |
| | sulfobutyl)-3H-indolium hydroxide, inner salt, sodium salt |
| 0.29 g | Coumarine 102 T |
| 6 g | Solution of 30 weight % in methyl ethyl ketone of an |
| | oligomer made by reaction of HMDI + HEMA + HEPi |
| 0.37 g | NK Ester BPE-500 |
| 0.25 g | 2,2-Bis(-2-chlorophenyl)-4,5,4′,5′-tetraphenyl-2′H- |
| | [1,2′]biimidazolyl |
| 0.15 g | 1H-1,2,4-triazole-5-thiol |
| | A mixture consisting of 31 ml of propylene glycol |
| | monomethyl ether, 19 ml of methanol and 23 ml of |
| | MEK was used to adjust the coating weight |

TABLE II

| | | |
|---|---|---|
| 4.72 | g | Polymer 2 (30% in MEK) |
| 1.4 | g | Polymer 3 |
| 0.2 | g | Basonyl Violet triphenylmethane contrast dye (10% in |
| | | methanol) |
| 3.2 | g | Urethane acrylate (80% solution in methyl ethyl ketone, |
| | | prepared by reacting Desmodur ® N100 with |
| | | hydroxyethyl acrylate and pentaerythritol triacrylate, 0.5 |
| | | double bonds per 100 g, when all isocyanate groups |
| | | have reacted) |
| 0.10 | g | Phenylimino diacetic acid |
| 0.09 | g | 2-[2-[2-Thiophenyl-3-[2-(1,3-dihydro-1,3,3-trimethyl- |
| | | 2H-indole-2-ylidene)-ethylidene]-1-cyclohexene-1-yl]- |
| | | ethenyl]-1,3,3-trimethyl-3H-indoliumchloride |
| 0.30 | g | 2-(4-Methoxyphenyl)-4,6-bis(trichloromethyl)-1,3,5- |
| | | triazine |
| 0.30 | g | 1H-1,2,4-triazole-5-thiol |
| 38 | ml | Propylene glycol monomethyl ether |
| 4 | ml | MEK |

Invention Developer 1 (% by Weight):

| | |
|---|---|
| Pluronic ® PE10400 | 2% |
| Mannose | 10% |
| Dehyton ® AB 30 | 15% |

Invention Developer 2 (% by Weight):

| | |
|---|---|
| Pluronic ® RPE 2035 | 4% |
| Lactose | 5% |
| Diethanol amine | 10% |
| Polyoxyethylene glycol naphthalene ether | 5% |

Invention Developer 3 (% by Weight):

| | |
|---|---|
| Pluronic ® PE6800 | 5% |
| Xylose | 3% |
| Triethanolamine | 10% |
| Texapon ® 842 | 5% |

Invention Developer 4 (% by Weight):

| | |
|---|---|
| Pluronic ® PE6400 | 1% |
| Desoxyribose | 5% |
| Ethanolamine | 10% |
| Texapon ® 842 | 30% |

Invention Developer 5 (% by Weight):

| | |
|---|---|
| Pluronic ® PE3100 | 10% |
| Ribulose | 1% |
| Diethanolamine | 3% |

Invention Developer 6 (% by Weight):

| | |
|---|---|
| Pluronic ® PE3500 | 4% |
| Glucose | 15% |
| Texapon ® 842 | 3% |

Invention Developer 7 (% by Weight):

| | |
|---|---|
| Pluronic ® PE4300 | 5% |
| Xylulose | 3% |
| Ethanolamine | 1% |

Invention Developer 8 (% by Weight):

| | |
|---|---|
| Pluronic ® PE8100 | 15% |
| Arabinose | 45% |
| Diethanolamine | 5% |

Invention Developer 9 (% by Weight)

| | |
|---|---|
| Pluronic ® PE6400 | 5% |
| Sorbitol | 5% |
| Diethanolamine | 10% |
| Texapon ® 842 | 15% |

Invention Developer 10 (% by Weight)

| | |
|---|---|
| Pluronic ® PE6400 | 5% |
| Xylitol | 5% |
| Diethanolamine | 10% |
| Texapon ® 842 | 15% |

Comparative Example Developer 1 (% by Weight):

| | |
|---|---|
| Pluronic ® PE8100 | 20% |
| Triethanolamine | 5% |
| Texapon ® 842 | 5% |

Comparative Example Developer 2 (% by Weight):

| | |
|---|---|
| Pluronic ® PE10400 | 10% |
| Diethanolamine | 10% |
| Polyoxyethylene glycol naphthalene ether | 1% |

Comparative Example Developer 3 (% by Weight):

| | |
|---|---|
| Xylose | 10% |
| Diethanolamine | 5% |

Comparative Example Developer 4 (% by Weight):

| | |
|---|---|
| Galactose | 5% |
| Ethanolamine | 15% |
| Amphotensid B5 | 5% |

TABLE III

| | | Running | | | | | | |
|---|---|---|---|---|---|---|---|---|
| | Plate | clean | Ink receptivity | Development | | Processor | | Length of |
| Developer | formulation | (number of | (number of | (speed in | Image Stability after 5 | cleanliness, | De-wetting | Run |
| (Example) | TABLE I | sheets) | sheets) | seconds) | days of processing | Grade 1 to 6 | Property | (LOR) |
| Invention 1 | 1 | 10 | 3 | 3 | No change, stable, | 2 | Dry plate | 100,000 |
| | | | | | non-image areas clean | | | |
| | | | | | after treatment with ink | | | |
| Invention 2 | 1 | 12 | 2 | 3 | No change, stable, | 1 | Dry plate | 110,000 |
| | | | | | non-image areas clean | | | |
| | | | | | after treatment with ink | | | |
| Invention 3 | 1 | 15 | 6 | 6 | No change, stable, | 2 | Dry plate | 100,000 |
| | | | | | non-image areas clean | | | |
| | | | | | after treatment with ink | | | |
| Invention 4 | 1 | 8 | 3 | 6 | No change, stable, | 1 | Dry plate | 100,000 |
| | | | | | non-image areas clean | | | |
| | | | | | after treatment with ink | | | |
| Invention 5 | 1 | 9 | 4 | 6 | No change, stable, | 1 | Dry plate | 120,000 |
| | | | | | non-image areas clean | | | |
| | | | | | after treatment with ink | | | |
| Invention 6 | 1 | 14 | 5 | 3 | No change, stable, | 2 | Dry plate | 100,000 |
| | | | | | non-image areas clean | | | |
| | | | | | after treatment with ink | | | |
| Invention 7 | 1 | 7 | 2 | 3 | No change, stable, | 2 | Dry plate | 120,000 |
| | | | | | non-image areas clean | | | |
| | | | | | after treatment with ink | | | |
| Invention 8 | 1 | 13 | 3 | 6 | No change, stable, | 1 | Dry plate | 120,000 |
| | | | | | non-image areas clean | | | |
| | | | | | after treatment with ink | | | |
| Invention 9 | 1 | 8 | 2 | 6 | No change, stable, | 1 | Dry plate | 135,000 |
| | | | | | non-image areas clean | | | |
| | | | | | after treatment with ink | | | |
| Invention 10 | 1 | 9 | 4 | 4 | No change, stable, | 1 | Dry plate | 130,000 |
| | | | | | non-image areas clean | | | |
| | | | | | after treatment with ink | | | |
| Invention 1 | 2 | 12 | 4 | 3 | No change, stable, | 2 | Dry plate | 110,000 |
| | | | | | non-image areas clean | | | |
| | | | | | after treatment with ink | | | |
| Invention 2 | 2 | 9 | 6 | 3 | No change, stable, | 2 | Dry plate | 100,000 |
| | | | | | non-image areas clean | | | |
| | | | | | after treatment with ink | | | |
| Invention 3 | 2 | 12 | 7 | 3 | No change, stable, | 2 | Dry plate | 110,000 |
| | | | | | non-image areas clean | | | |
| | | | | | after treatment with ink | | | |
| Invention 4 | 2 | 6 | 2 | 3 | No change, stable, | 2 | Dry plate | 100,000 |
| | | | | | non-image areas clean | | | |
| | | | | | after treatment with ink | | | |
| Invention 5 | 2 | 17 | 3 | 3 | No change, stable, | 1 | Dry plate | 100,000 |
| | | | | | non-image areas clean | | | |
| | | | | | after treatment with ink | | | |
| Invention 6 | 2 | 13 | 3 | 6 | No change, stable, | 2 | Dry plate | 100,000 |
| | | | | | non-image areas clean | | | |
| | | | | | after treatment with ink | | | |
| Invention 7 | 2 | 14 | 2 | 6 | No change, stable, | 1 | Dry plate | 100,000 |
| | | | | | non-image areas clean | | | |
| | | | | | after treatment with ink | | | |
| Invention 8 | 2 | 16 | 4 | 6 | No change, stable, | 1 | Dry plate | 100,000 |
| | | | | | non-image areas clean | | | |
| | | | | | after treatment with ink | | | |
| Invention 9 | 2 | 11 | 3 | 6 | No change, stable, | 1 | Dry plate | 120,000 |
| | | | | | non-image areas clean | | | |
| | | | | | after treatment with ink | | | |
| Invention 10 | 2 | 9 | 4 | 6 | No change, stable, | 1 | Dry plate | 110,000 |
| | | | | | non-image areas clean | | | |
| | | | | | after treatment with ink | | | |
| Comparative 1 | 1 | 31 | 16 | 18 | Not stable, image | 4 | Wet plate | 50,000 |
| | | | | | partially disappeared, | | | |
| | | | | | toning | | | |
| Comparative 2 | 1 | 50 | 13 | 18 | Not stable, image | 4 | Wet plate | 30,000 |
| | | | | | partially disappeared, | | | |
| | | | | | toning | | | |
| Comparative 3 | 1 | 25 | 12 | 21 | Not stable, image | 6 | Wet plate | 40,000 |
| | | | | | partially disappeared, | | | |
| | | | | | toning | | | |
| Comparative 4 | 1 | 60 | 15 | 12 | Not stable, image | 5 | Wet plate | 50,000 |
| | | | | | partially disappeared, | | | |
| | | | | | toning | | | |
| Comparative 1 | 2 | 33 | 18 | 15 | Not stable, image | 5 | Wet plate | 50,000 |
| | | | | | partially disappeared, | | | |
| | | | | | toning | | | |
| Comparative 2 | 2 | 52 | 16 | 15 | Not stable, image | 6 | Wet plate | 30,000 |
| | | | | | partially disappeared, | | | |
| | | | | | toning | | | |
| Comparative 3 | 2 | 29 | 14 | 21 | Not stable, image | 5 | Wet plate | 40,000 |
| | | | | | partially disappeared, | | | |
| | | | | | toning | | | |
| Comparative 4 | 2 | 64 | 19 | 21 | Not stable, image | 6 | Wet plate | 50,000 |
| | | | | | partially disappeared, | | | |
| | | | | | toning | | | |

The results shown in TABLE III demonstrate that the aqueous developers of the present invention provide a simplified and effective way to process imaged negative-working lithographic printing plate precursors. Specifically, these results demonstrate that the present invention can be used to process an imaged precursor in one developer bath without any additional prewash, post-development rinse, or gumming steps resulting in a long-run lithographic printing plate even after storage for several days in processing chemicals.

The invention has been described in detail with particular reference to certain preferred embodiments thereof, but it will be understood that variations and modifications can be effected within the spirit and scope of the invention.

1. An aqueous developer composition for processing imaged negative-working lithographic printing plate precursors, the developer having a pH of at least 4 and up to and including 13, and comprising both the following (a) and (b):
(a) at least one ethylene glycol/propylene glycol block copolymer in an amount of at least 1 weight %, and
(b) one or more compounds selected from the group consisting of the following (i), (ii), and (iii) in a total amount of at least 1 weight %:
(i) at least one non-reducing sugar alcohol having the formula H(HCHO)ₙ₊₁H wherein n is 5 or 6,
(ii) at least one non-reducing monosaccharide having the formula H(HCHO)ₙHCO wherein n is 5 or 6, and
(iii) at least one non-reducing oligosaccharide having the formula H(HCHO)ₙHCO wherein n is 5 or 6.

2. The aqueous developer composition of claim 1 wherein the weight ratio of the block copolymer to the total (i), (ii), and (iii) compounds is from 1:20 to 20:1.

3. The aqueous developer composition of claim 1 wherein the (ii) and (iii) compounds are selected from the group consisting of mannose, lactose, xylose, desoxyribose, ribulose, glucose, fructose, furanose, pyranose, sucrose, galactose, maltose, raffinose, D,L-arabitol, ribitol, sorbitol, and D,L-xylitol, D,L-mannitol, D,L-talitol, meso-inositol, dulcitol, and alloducitol.

4. The aqueous developer composition of claim 1 wherein the total of (i), (ii), and (iii) compounds is an amount of at least 1 and up to and including 20 weight %.

5. The aqueous developer composition of claim 1 wherein the ethylene glycol/propylene glycol block copolymer is present in an amount of at least 1 and up to and including 20 weight %.

6. The aqueous developer composition of claim 1 wherein the ethylene glycol/propylene glycol block copolymer has a weight average molecular weight of at least 400 and up to and including 15,000.

7. The aqueous developer composition of claim 1 having a pH of at least 4 and up to and including 11.

8. The aqueous developer composition of claim 1 further comprising one or more anionic, nonionic, cationic, or amphoteric surfactants in a total amount of up to 40 weight %.

9. The aqueous developer composition of claim 1 further comprising an anionic surfactant in an amount of at least 0.5 and up to and including 5 weight %.

10. The aqueous developer composition of claim 1 that is free of silicates and metasilicates.

11. The aqueous developer composition of claim 1 further comprising an alcoholamine.

12. A method of providing a lithographic printing plate comprising:
A) imagewise exposing a negative-working lithographic printing plate precursor having a hydrophilic substrate and an imageable layer disposed on the hydrophilic substrate, to provide exposed and non-exposed regions in the imageable layer of the imagewise exposed precursor,
the imageable layer comprising a free radically polymerizable component, an initiator composition that provides free radicals upon imagewise exposure, a radiation absorbing compound, and a polymer binder, and
B) with or without a preheat step, processing the imagewise exposed precursor with the aqueous developer composition of claim 1, to remove the non-exposed regions in the imageable layer.

13. The method of claim 12 wherein the lithographic printing plate precursor is sensitive to near infrared or infrared radiation and the imagewise exposing is carried out at the wavelength of at least 700 nm and up to and including 1400 nm.

14. The method of claim 12 wherein the lithographic printing plate precursor is sensitive to and imagewise exposed at the wavelength of at least 350 nm and up to and including 450 nm.

15. The method of claim 12 wherein the imaged and developed lithographic printing plate is used for printing without any additional solution treatment after the developing step.

16. The method of claim 12 wherein processing step B is carried out by intermittent or continuous replenishment using fresh portions of the aqueous developer composition.

17. The method of claim 16 wherein the aqueous developer composition is replenished with water only.

18. The method of claim 12 wherein processing step B is carried out without any replenishment of the aqueous developer composition.

19. A kit comprising:
one or more negative-working lithographic printing plate precursors having a hydrophilic substrate and an imageable layer disposed on the hydrophilic substrate, the imageable layer comprising a free radically polymerizable component, an initiator composition that provides free radicals upon imagewise exposure, a radiation absorbing compound, and a polymer binder, and
the aqueous developer composition of claim 1.

20. The kit of claim 19 wherein the aqueous developer composition has a pH of at least 4 and up to and including 11 and is free of silicates and metasilicates.
